(19) United States
(12) Patent Application Publication
(10) Pub. No.: US 2014/0151341 A1
(43) Pub. Date: Jun. 5, 2014

(54) WIRE BONDING APPARATUS

(71) Applicant: Shinkawa Ltd., Tokyo (JP)

(72) Inventors: Katsutoshi KUNIYOSHI, Tokyo (JP); Hayato KIUCHI, Tokyo (JP)

(73) Assignee: Shinkawa Ltd., Tokyo (JP)

(21) Appl. No.: 14/170,745

(22) Filed: Feb. 3, 2014

Related U.S. Application Data
(63) Continuation of application No. PCT/JP2012/063844, filed on May 30, 2012.

(30) Foreign Application Priority Data
Aug. 16, 2011 (JP) 2011-178019
Dec. 20, 2011 (JP) 2011-278335

(51) Int. Cl. H01L 23/00; B23K 9/16

(52) U.S. Cl. CPC H01L 24/78; B23K 9/164
USPC 219/74; 228/4.5

(57) ABSTRACT

Provided with a wire bonding apparatus capable of preventing oxidation of a surface of a free air ball. The apparatus is provided with: a capillary for bonding a wire to each electrode; a horizontal plate provided with a through hole allowing a tip of the capillary to be inserted and removed; and a first and a second antioxidant gas flow channel for allowing an antioxidant gas to be blown to a center of the through hole along an upper surface of the horizontal plate, the gas from the second channel being blown in a direction substantially intersecting with a direction in which the first channel extends. The horizontal plate is configured such that the antioxidant gas on the upper surface of the horizontal plate is allowed to flow outside the horizontal plate from its edges, where no antioxidant gas flow channel is disposed.

### TECHNICAL FIELD

The present invention relates to a structure of wire bonding apparatuses.

### BACKGROUND ART

When connecting an electrode of a substrate and an electrode of a semiconductor chip with a metal wire by a wire bonding apparatus, a wire bonding method is employed that includes: causing a spark between a metal wire extending from a tip of a bonding tool and an Electronic Flame-Off (EFO) to thereby form a free air ball; bonding the free air ball on one of the electrodes (ball bonding); looping the wire to the top of the other electrode while paying out the wire from the tip of the bonding tool; and bonding the wire to the other electrode. A gold wire, which is non-oxidizing, is commonly used in the wire bonding operation because bonding between either electrode and one of the metal wire and the free air ball may often result in defective if a surface of the metal wire or a surface of the free air ball is oxidized by air.

In contrast, in recent years, there has been proposed a wire bonding method using a metal wire that oxidizes such as copper or aluminum. When wire bonding is performed using such an oxidizing metal wire, it is necessary to prevent oxidation of a surface of the metal wire. Patent literature 1 (Japanese Unexamined Patent Application Publication No. 2007-294975), for example, proposes a method for preventing oxidation of a surface of a metal wire by blowing an antioxidant gas toward a free air ball formation area or a surface of an electrode that is to be bonded to form an antioxidant gas atmosphere in the free air ball formation area or an area around the electrode.

As another example, Patent literature 2 (Japanese Unexamined Patent Application Publication No. 2008-130825) proposes a method including: arranging a gas cover so as to surround a free air ball formation area; blowing an antioxidant gas into a cavity in the center of the gas cover from a periphery of the gas cover through a porous component attached within the gas cover, to thereby form an antioxidant gas atmosphere in the cavity; and causing a spark between a wire and an electrode of EFO in the antioxidant gas atmosphere to form a free air ball.

### RELATED ART DOCUMENTS

### Patent literature

Patent literature 1 JP2007-294975
Patent literature 2 JP2008-130825

### SUMMARY OF THE INVENTION

### Problems to be Resolved by the Invention

However, when an antioxidant gas is blown from a tip of a pipe toward the free air ball formation area as described in Patent literature 1, the flow rate of the antioxidant gas is required to be high in order to maintain the antioxidant gas atmosphere in the free air ball formation area. This poses a problem that a fine free air ball can not be formed because the free air ball is cooled by the antioxidant gas during the formation of the ball.

Further, as a wire bonding apparatus performs wire bonding by moving a bonding tool up and down, the bonding tool is to be moved up and down within the cavity when the free air ball formation area is surrounded by the gas cover and forming an antioxidant gas atmosphere within the cavity in the center of the gas cover by blowing an antioxidant gas into the cavity as described in Patent literature 2.

When forming the free air ball, the wire bonding apparatus raises a tip of the bonding tool into the cavity and then generates a spark between the electrode of EFO and the wire extending from the tip of the bonding tool. Upon raising the bonding tool, however, stagnant air around the bonding tool accompanies the bonding tool and comes into the cavity. Even though the antioxidant gas blows from the circumference of the cavity, the air that has entered the cavity is shielded by the gas cover and may not be easily exhausted outside. This often results in a case in which the atmosphere within the cavity remains air atmosphere that contains oxygen, and a spark is caused in that air atmosphere to form a free air ball. Accordingly, the conventional technique described in Patent literature 2 is not able to prevent oxidation of the metal surface of the free air ball when forming the free air ball, posing a problem of poor bonding quality when performing a wire bonding operation using a metal wire that oxidizes in the air, such as copper.

An object of the present invention is to prevent oxidation of a surface of a free air ball in a wire bonding apparatus.

### Means for Solving the Problems

A wire bonding apparatus of the present invention is for bonding an electrode of a semiconductor chip and an electrode of a substrate with a wire, and the apparatus is provided with: a bonding tool for bonding a wire to each electrode; a horizontal plate provided with a through hole allowing a tip of the bonding tool to be inserted and removed; a first antioxidant gas flow channel for allowing an antioxidant gas to be blown to a center of the through hole along an upper surface of the horizontal plate; and a second antioxidant gas flow channel for allowing an antioxidant gas to be blown to the center of the through hole along the upper surface of the horizontal plate in a direction substantially intersecting with a direction in which the first antioxidant gas flow channel extends, wherein the horizontal plate is configured such that the antioxidant gas on the upper surface of the horizontal plate is allowed to flow outside the horizontal plate from edges of the horizontal plate, the edges being provided with no antioxidant gas flow channel.

In the wire bonding apparatus according to the present invention, it is preferable that a wall surface is further provided vertically and upright on the upper surface of the horizontal plate, around a periphery of an outlet of the first antioxidant gas flow channel, around a periphery of an outlet of the second antioxidant gas flow channel, and between the peripheries, the wall surface having the antioxidant gas be stagnated thereabout. It is also preferable that the wall surface is provided spaced apart from a periphery of the through hole in the horizontal plate.

In the wire bonding apparatus according to the present invention, it is preferable that a portion of each antioxidant gas flow channel connecting to the corresponding outlet is a straight pipe conduit extending along the upper surface of the horizontal plate, and wherein a guide vane for preventing the antioxidant gas from drifting is provided within an interior portion of each straight pipe conduit. It is also preferable that each guide vane includes flat plates disposed in a crosswise manner, partitioning a cross section of the straight pipe conduit into four sections, and wherein the flat plates are arranged in a manner inclined with respect to the upper surface of the horizontal plate.

In the wire bonding apparatus according to the present invention, it is preferable that the wire bonding apparatus is provided with a third antioxidant gas flow channel for allowing an antioxidant gas to be blown to the center of the through hole obliquely downward from a lower surface of the horizontal plate. It is preferable that the first antioxidant gas flow channel, the second antioxidant gas flow channel, the third antioxidant gas flow channel, and the horizontal plate are provided for a common base unit, and the common base unit includes a wall surface arranged around a periphery of an outlet of the first antioxidant gas flow channel, around a periphery of an outlet of the second antioxidant gas flow channel, and between the peripheries, the wall surface having the antioxidant gas be stagnated thereabout. In addition, it is preferable that the third antioxidant gas flow channel allows the antioxidant gas to be blown to the tip of the bonding tool.

In the wire bonding apparatus according to the present invention, it is preferable that an electrode of electronic flame off (EFO) is provided for forming a free air ball by generating a spark between the wire extending at the tip of the bonding tool and thereof, and the electrode of EFO extends from either one of the outlets of the first and second antioxidant gas flow channels toward the through hole of the horizontal plate.

### Advantageous Effect of the Invention

The present invention provides an advantageous effect of preventing oxidation of a surface of a free air ball in the wire bonding apparatus.

### BRIEF DESCRIPTION OF DRAWINGS

Exemplary embodiments of the present invention will be described in detail with reference to the accompanying drawings, wherein:

FIG. 1 is a perspective view illustrating an antioxidant unit of a wire bonding apparatus according to an exemplary embodiment of the present invention;

FIG. 2 is a plan view illustrating an antioxidant unit of the wire bonding apparatus according to an exemplary embodiment of the present invention;

FIG. 3 is a perspective view illustrating the configuration of a guide vane provided for the antioxidant unit of the wire bonding apparatus according to an exemplary embodiment of the present invention;

FIG. 4 is a sectional view illustrating a cross-section of an antioxidant gas flow channel provided for the antioxidant unit of the wire bonding apparatus according to an exemplary embodiment of the present invention;

FIG. 5 is an elevational view illustrating an operation of the wire bonding apparatus and the antioxidant unit according to an exemplary embodiment of the present invention;

FIG. 6 is an elevational view illustrating an operation of the wire bonding apparatus and the antioxidant unit according to an exemplary embodiment of the present invention;

FIG. 7 is a plan view illustrating an operation of the wire bonding apparatus and the antioxidant unit according to an exemplary embodiment of the present invention;

FIG. 8 is a perspective view illustrating an antioxidant unit of the wire bonding apparatus according to a different exemplary embodiment of the present invention;

FIG. 9 is a plan view illustrating an antioxidant unit of the wire bonding apparatus according to the different exemplary embodiment of the present invention;

FIG. 10 is an elevational view illustrating an operation of the wire bonding apparatus and the antioxidant unit according to a different exemplary embodiment of the present invention;

FIG. 11 is an elevational view illustrating an operation of the wire bonding apparatus and the antioxidant unit according to the different exemplary embodiment of the present invention; and

FIG. 12 is a plan view illustrating an operation of the wire bonding apparatus and the antioxidant unit according to a different exemplary embodiment of the present invention.

### DETAILED DESCRIPTION OF THE INVENTION

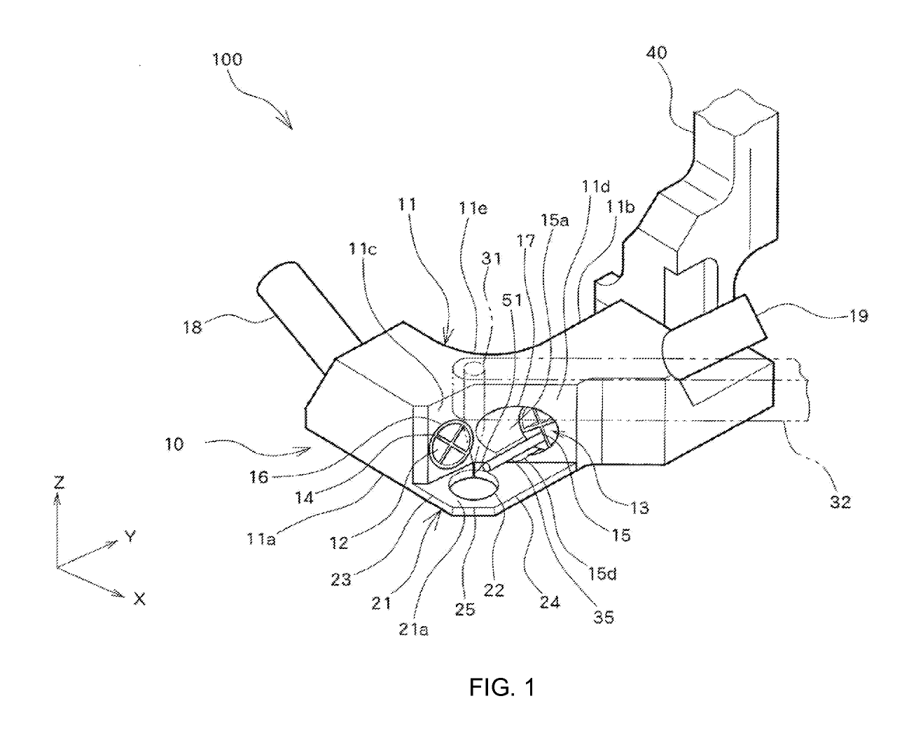

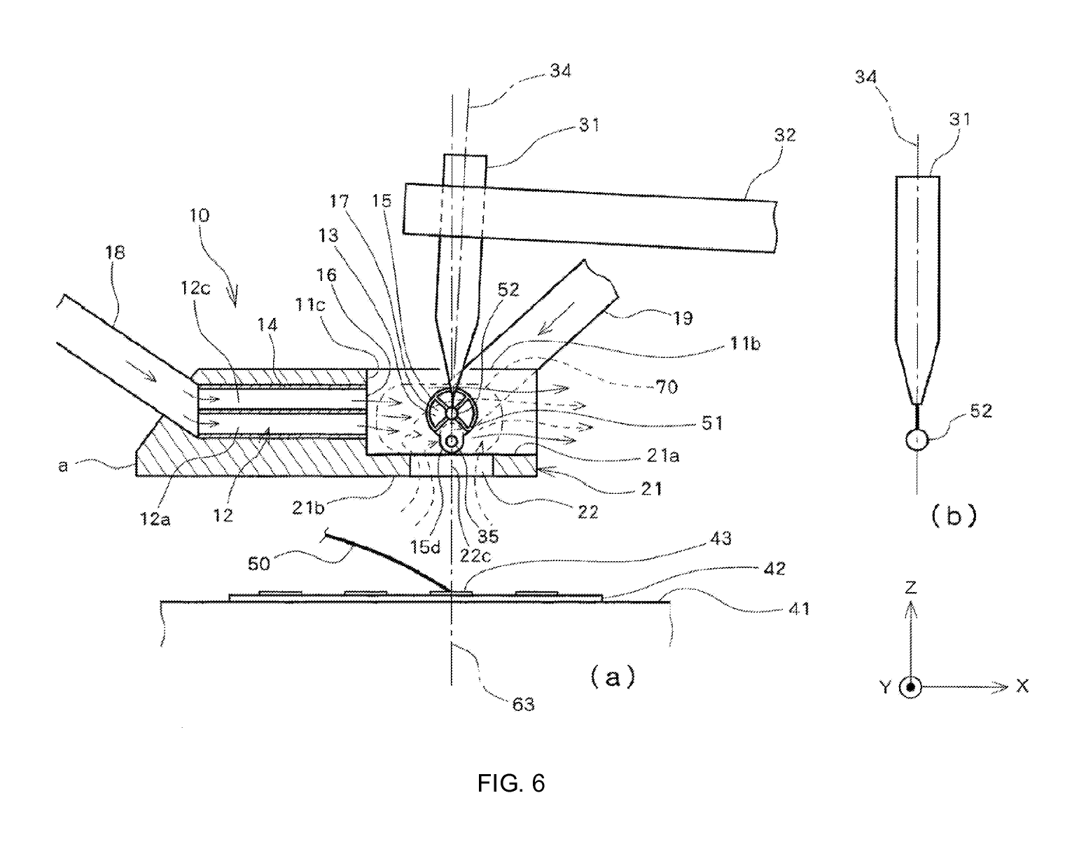

Hereinafter, an exemplary embodiment according to the present invention will be described in detail with reference to the accompanying drawings. As shown in FIG. 1, a wire bonding apparatus 100 of the exemplary embodiment is provided with: a capillary 31 serving as a bonding tool for bonding a wire to an electrode of a semiconductor chip or a substrate; a bonding arm 32 attached to an ultrasonic horn (not shown) for moving the capillary 31 in the up-and-down direction; an antioxidant unit 10 for maintaining an antioxidant gas atmosphere in an area in which a free air ball 52 shown in FIG. 6(b) is formed from a wire tail 51 extending at a tip of the capillary 31, thereby preventing oxidation of a surface of the free air ball 52. The bonding arm 32 and the antioxidant unit 10 are attached to a bonding head (not shown), and are configured to move together in a horizontal direction. Note that, in FIG. 1, a vertical direction is a Z direction, and X and Y represent horizontal directions that are at a right angle to each other. This also applies to other figures.

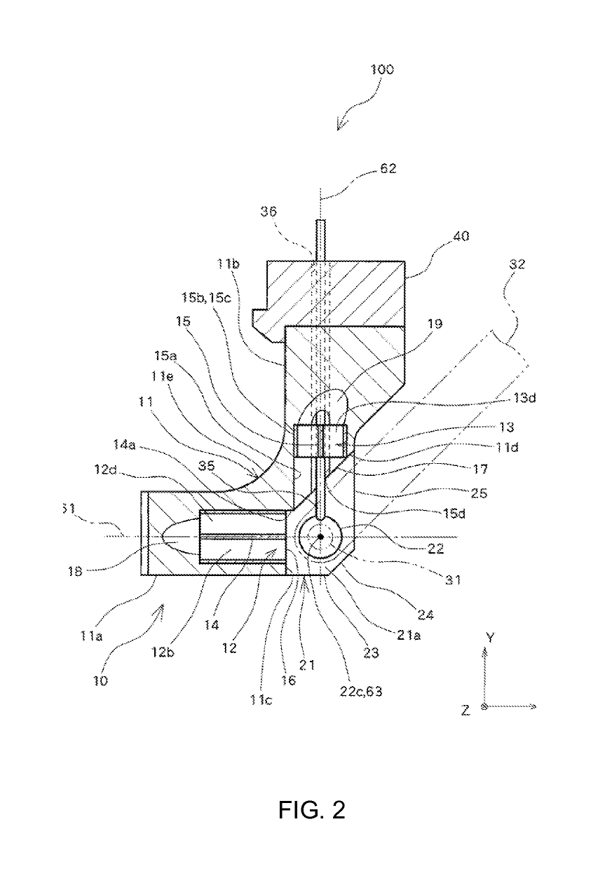

The antioxidant unit 10 includes a main body 11 made of plastic or an insulating material and a mounting arm 40 for mounting the main body 11 to the bonding head (not shown). As shown in FIG. 1 and FIG. 2, the main body 11 is configured such that a substantially cuboid first block 11a, a second block 11b that is substantially trapezoid in a planar view, and a horizontal plate 21 are combined in an overall L shape, and corners of the first block 11a on the side of the second block 11b and corners of a long side of the second block 11b are unitarily formed. A curved surface 11e continues from a lateral surface of the first block 11a to a lateral surface of the second block 11b forming a concave portion on the side opposite of the side on which a through hole is provided. Also, a vertical wall surface 11c of the first block 11a and a vertical wall surface 11d of the second block 11b on the oblique side are located adjacently. The horizontal plate 21 connecting a bottom surface of the first block 11a and a bottom surface of the second block 11b extends at a right angle to the vertical wall surface 11c of the first block 11a and the vertical wall surface 11d of the second block 11b, i.e., in a horizontal direction (XY direction). Specifically, the main body 11 is configured such that the first block 11a and the second block 11b constitute arms respectively extending along centerlines 61 (X-direction centerline) and 62 (Y-direction centerline) at a right angle to each other as shown in FIG. 2, the horizontal plate 21 is located so as to connect the arms at a crossing portion therebetween, and the first block 11a, the second block 11b, and the horizontal plate 21 are combined in an overall L shape. Also, as shown in FIG. 2, a through hole 22 is provided in the horizontal plate 21 such that a center 22c of the through hole 22 is positioned at an intersection between the centerline 61 (X-direction centerline) of the first block 11a and the centerline 62 (Y-direction centerline) of the second block 11b. Moreover, as shown in FIG. 1 and FIG. 2, the capillary 31 is arranged such that its center is coincident with the center 22c of the through hole 22.

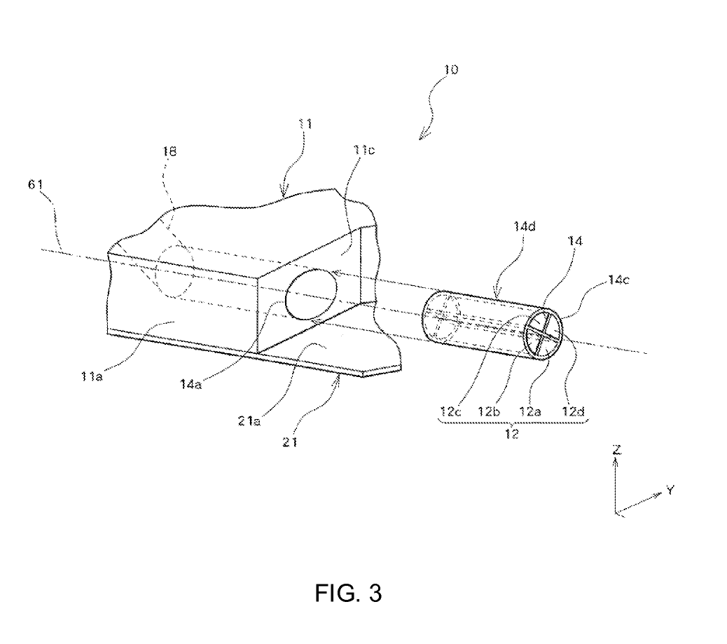

The first block 11a is provided with a straight first antioxidant gas flow channel 12 extending along the centerline 61 (X-direction centerline) shown in FIG. 2. As shown in FIG. 3, the first antioxidant gas flow channel 12 is configured such that a guide vane assembly 14b is fitted in a first hole 14a in the vertical wall surface 11c of the first block 11a with respect to the horizontal plate 21 and extending along the centerline 61 (X-direction centerline). The guide vane assembly 14b includes a cylindrical external cylinder 14c and a guide vane 14 in which flat plates are disposed in a crosswise manner. Upon fitting the guide vane assembly 14b into the first hole 14a, the guide vane 14 of the guide vane assembly 14b constitutes four flow channel sections 12a to 12d having a fan-shaped cross-section. The guide vane assembly 14b is fitted into the first hole 14a of the first block 11a such that the flat plates of the guide vane 14 are inclined at 45 degrees with respect to an upper surface 21a of the horizontal plate 21. Accordingly, out of the four fan-shaped flow channel sections 12a to 12d, the flow channel sections 12a and 12c are aligned along a vertical direction, and the flow channel sections 12b and 12d are aligned along a horizontal direction. The flow channel sections 12a to 12d together constitute the first antioxidant gas flow channel 12. Also, as shown in FIG. 3, the first antioxidant gas supply line 18, which extends obliquely upward from the first block 11a, is connected to the first antioxidant gas flow channel 12 on the side opposite of the vertical wall surface 11c. Further, as shown in FIG. 1 and FIG. 2, an opening of the first antioxidant gas flow channel 12 in the vertical wall 11c of the first block 11a constitutes a first antioxidant gas outlet 16 from which the antioxidant gas is blown toward the through hole 22 in the horizontal plate 21.

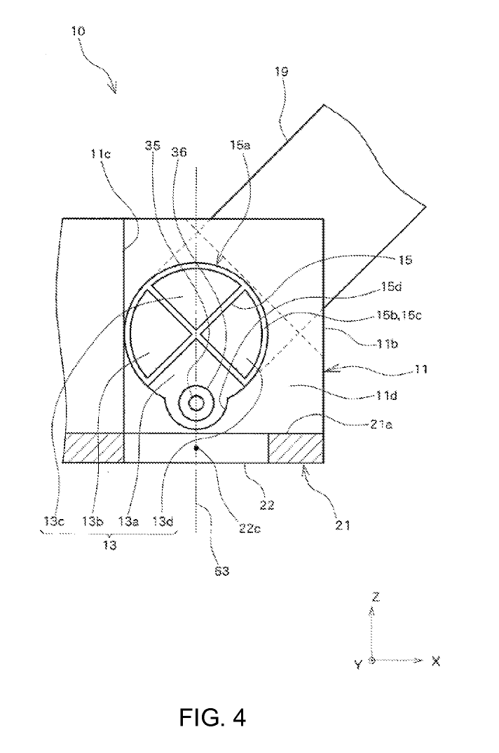

The second block 11b is provided with a straight second antioxidant gas flow channel 13 for extending along the centerline 62 (Y-direction centerline) as shown in FIG. 2. As shown in FIG. 4, the second antioxidant gas flow channel 13 is configured such that a guide vane assembly 15b is fitted in a second hole 15a in the vertical wall surface 11d of the second block 11b with respect to the horizontal plate 21 and extending along the centerline 62 (Y-direction centerline). The guide vane assembly 15b is configured such that a guide vane 15 in which inclined flat plates are disposed in a crosswise manner is attached to an external cylinder 15c. The guide vane 15 constitutes four flow channel sections 13a to 13d having a fan-shaped cross-section, and the flow channel sections 13a to 13d together constitute the second antioxidant gas flow channel 13. Also, as shown in FIG. 2 and FIG. 4, the second antioxidant gas supply line 19, which extends obliquely upward from the second block 11b, is connected to the second antioxidant gas flow channel 13 on the side opposite of the vertical wall surface 11d. Further, an opening of the second antioxidant gas flow channel 13 in the vertical wall 11d of the second block 11b constitutes a second antioxidant gas outlet 17 from which the antioxidant gas is blown toward the through hole 22 in the horizontal plate 21. As shown in FIG. 2, the vertical wall 11d is inclined to the centerline 62 (Y-direction centerline), and therefore the second antioxidant gas outlet 17 is in an elliptical shape as shown in FIG. 1.

As shown in FIG. 4, the second hole 15a is provided with a groove 15d having a semicircular cross-section in its bottom surface. As shown in FIG. 1 and FIG. 2, the groove 15d extends along the centerline 62 (Y-direction centerline) of the second block 11b, and an electrode 35 of EFO for generating a spark between the electrode 35 and the wire tail 51 extending from the tip of the capillary 31 to form the free air ball 52 shown in FIG. 6(b) is disposed in the groove 15d. The electrode 35 of EFO extends to the mounting arm 40 on the side opposite to the vertical wall 11d of the second block 11b, and outside through a mounting hole 36 for the electrode of EFO which passes through the mounting arm 40 and the second block 11b to be connected to an external power-supply unit. Also, the electrode 35 of EFO is insertable into and removable from the mounting hole 36 of EFO, and may be replaced without disassembling another part of the antioxidant unit 10.

As shown in FIG. 4, while the electrode of EFO extends along the bottom surface of the flow channel sections 13a which is the lowermost one of the four fan-shaped flow channel sections 13a to 13d partitioned by the cross-shaped guide vane 15, a cross-sectional area of the flow channel section 13a is greater than those of the other flow channel sections 13b to 13d by a cross-sectional area of the groove 15d. Therefore, an amount of the antioxidant gas that flows through the flow channel section 13a is as much as that flows through each of the other flow channel sections 13b to 13d.

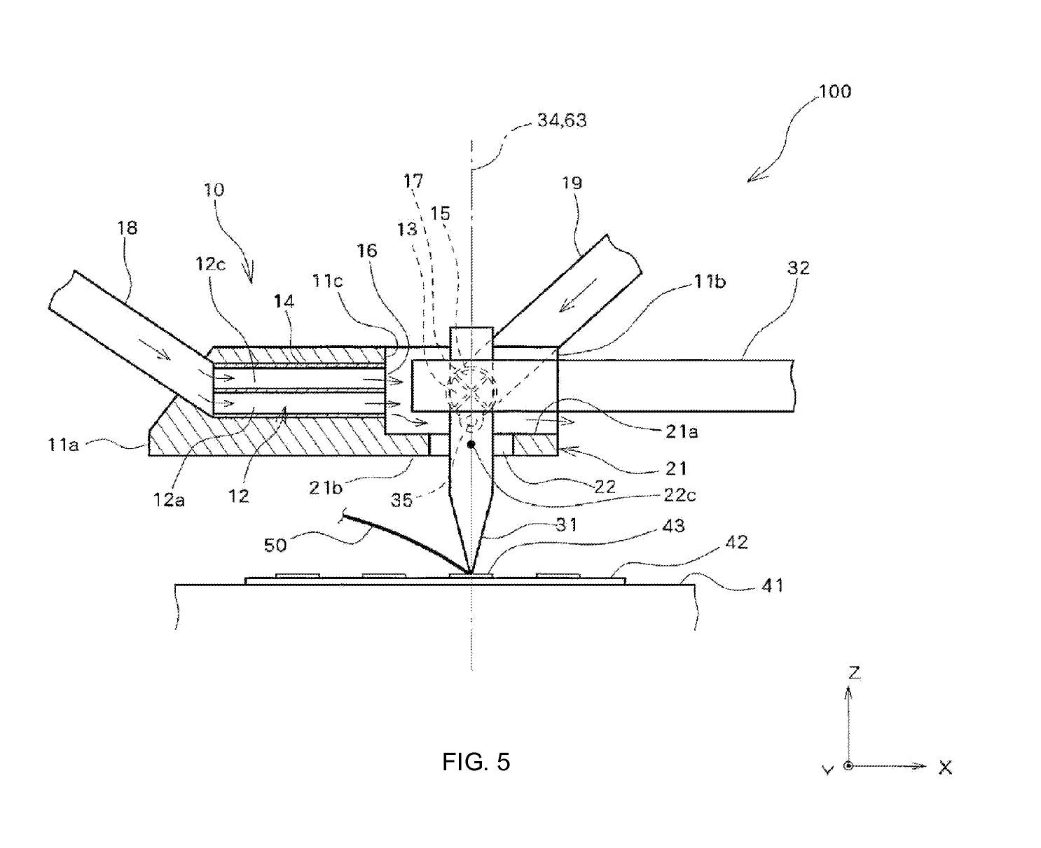

Now, an operation of the wire bonding apparatus 100 thus configured will be described with reference to FIG. 5 to FIG. 7. FIG. 5 shows a state in which a wire 50 is bonded on an electrode 43 of a substrate 42 suctioned to a bonding stage 41. In this state, the tip of the capillary 31 comes at a surface of the electrode 43 through the through hole 22, and a centerline 34 of the capillary 31 in an up-and-down direction and a centerline 63 (Z-direction centerline) of the through hole 22 are on the same axis, which also passes a center of the electrode 43; therefore, the tip of the capillary 31 is positioned at the center of the electrode 43. Also, as shown by arrows in a solid line in FIG. 5, the antioxidant gas is supplied from the first and second antioxidant gas supply lines 18, 19 to the first and second antioxidant gas flow channels 12, 13, respectively, and blown through the outlets 16, 17 toward the center 22c of the through hole 22.

As shown in FIG. 6(a), upon completing bonding of the wire 50 to the electrode 43, the capillary 31 attached to a tip of the bonding arm 32 is raised by rotation of the bonding arm 32. As the capillary 31 rises, the wire tail 51 extends from the tip of the capillary 31. When the wire tail 51 becomes a predetermined length, then the wire is cut off by raising the wire together with the capillary 31 while being clamped by a clamper (not shown). This results in the wire tail 51 of a predetermined length extending from the tip of the capillary 31. Then, the capillary is further raised up to a position at which the tip of the capillary 31 comes above the upper surface 21a of the horizontal plate 21 and a lower end of the wire tail 51 comes near a center position of the electrode 35 of EFO.

When the capillary 31 rises, periphery air of the capillary 31 accompanies the capillary 31 through the through hole 22 above the upper surface 21a of the horizontal plate 21, as shown by arrows in a dotted line in FIG. 6(a).

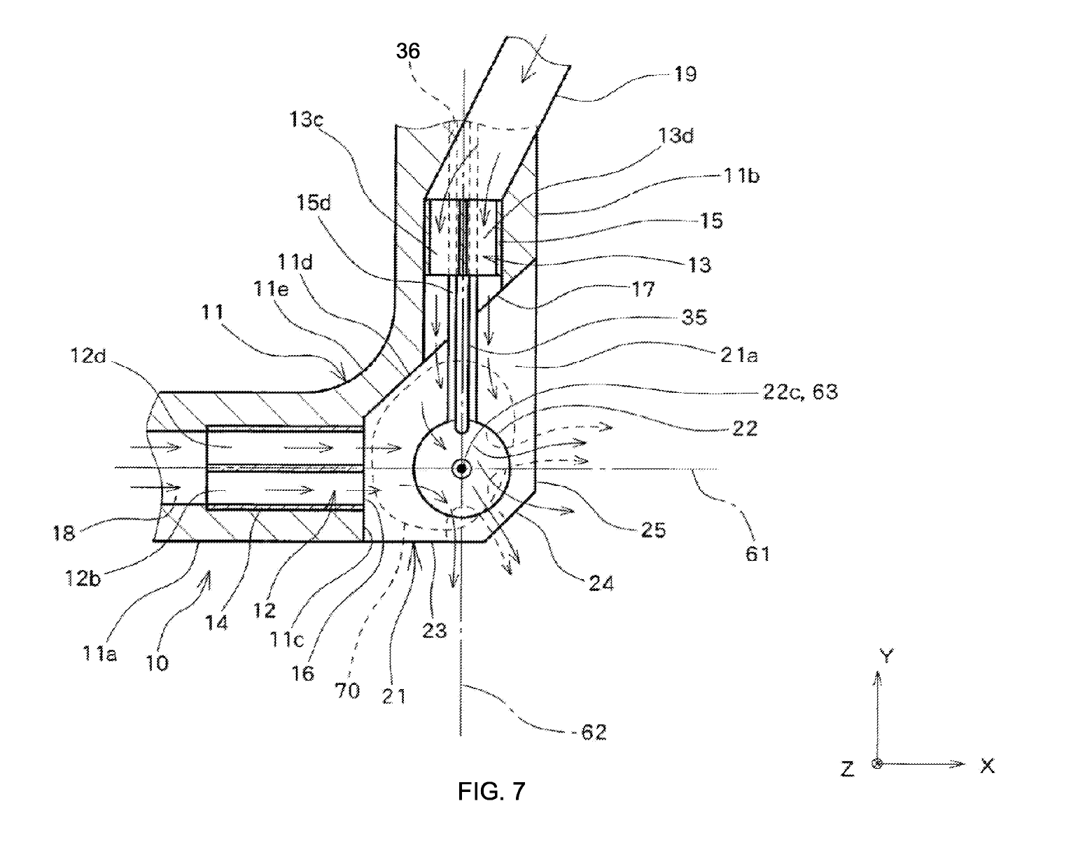

At the same time, as shown by arrows in a solid line in FIG. 6(a), the antioxidant gas is blown through the outlets 16, 17 of the first and second antioxidant gas flow channels 12, 13 toward the center 22c of the through hole 22 along the upper surface 21a of the horizontal plate 21. As shown in FIG. 7, flows of the antioxidant gas respectively from the outlets 16, 17 move along the centerline 61 (X-direction centerline) and the centerline 62 (Y-direction centerline) over the horizontal plate 21, meet above the through hole 22, and then move outside of the horizontal plate 21 from edges of the horizontal plate 21 that are open without being provided with an antioxidant gas flow channel or a vertical wall surface; the edges including an edge 25 perpendicular to the centerline 61 (X-direction centerline), an edge 23 perpendicular to the centerline 62 (Y-direction centerline), and an edge 24 inclined to the centerline 61 (X-direction centerline) and the centerline 62 (Y-direction centerline). In this case, as shown by arrows in a dotted line in in FIG. 6(a) and FIG. 7, air that has come above the upper surface 21a of the horizontal plate 21 through the through hole 22 move outside of the horizontal plate 21 from the edges 23, 24, and 24 that are opened and without being provided with the vertical walls 11c, 11d, along with the antioxidant gas shown by the arrows in a solid line. Also, the antioxidant gas blown from the outlets 16, 17 forms a stagnant area by the vertical walls 11c, 11d of the first and second blocks 11a, 11b forming the wall surfaces perpendicular to the horizontal plate 21 to form an antioxidant gas atmosphere area 70 that spreads horizontally including an area of the through hole 22 and an area between the through hole and the vertical walls 11c, 11d, with a height from the upper surface 21a of the horizontal plate 21 to top edges of the vertical walls 11c, 11d, as shown in FIG. 6(a) and FIG. 7.

As the antioxidant gas atmosphere area 70 is formed only after air that has come above the horizontal plate 21 is emitted outside through the edges 23 to 25 as described above, the antioxidant gas atmosphere area 70 may become an area that does not contain oxygen. When forming the free air ball 52 at the tip of the capillary 31, as shown in FIG. 6(b) by generating a spark between the electrode 35 of EFO and the wire tail 51 of the tip of the capillary 31 in the antioxidant gas atmosphere area 70, it is possible to effectively prevent oxidation of the surface of the free air ball 52 because the antioxidant gas atmosphere area 70 does not include air containing oxygen.

Further, in the exemplary embodiment, since the cross-shaped guide vanes 14, 15 respectively of the first and second antioxidant gas flow channels 12, 13 are arranged such that the flat plates of the guide vanes 14, 15 are inclined at 45 degrees with respect to the upper surface 21a of the horizontal plate 21, the flow channel sections 12a, 12c and 13a, 13c of the four fan-shaped flow channel sections 12a to 12d and 13a to 13d are aligned along the vertical direction, and the flow channel sections 12b, 12d and 13b, 13d of the four fan-shaped flow channel sections are aligned along the horizontal direction. As the flow channel sections 12a to 12d are arranged as just described, even if the first antioxidant gas supply line 18 is connected to the first antioxidant gas flow channel 12 in an inclined manner with respect to the vertical direction and the horizontal direction as in the exemplary embodiment, the flow rate of the antioxidant gas flowing through each of the flow channel sections 12a to 12d becomes substantially the same. Similarly, even if the second antioxidant gas supply line 19 is connected to the second antioxidant gas flow channel 13 in an inclined manner with respect to the vertical direction and the horizontal direction, the flow rate of the antioxidant gas flowing through each of the flow channel sections 13a to 13d becomes substantially the same. As this effectively prevent the antioxidant gas blown through the outlets 16, 17 toward the through hole 22 from drifting downward disproportionately, the height of the antioxidant gas atmosphere area 70 on the horizontal plate 21 may be increased. Thus, it is possible to effectively prevent oxidation of the surface of the free air ball 52 in various bonding conditions, and to improve bonding quality using a metal wire that oxidizes in the air, such as copper or aluminum.

In the exemplary embodiment, it is described that the outlets 16, 17 are at a right angle to the XY direction. However, the each outlets 16, 17 may not be at a right angle to each other, as long as the flows of the antioxidant gas blown from the respective outlets to the center 22c of the through hole 22 meet each other above the through hole 22.

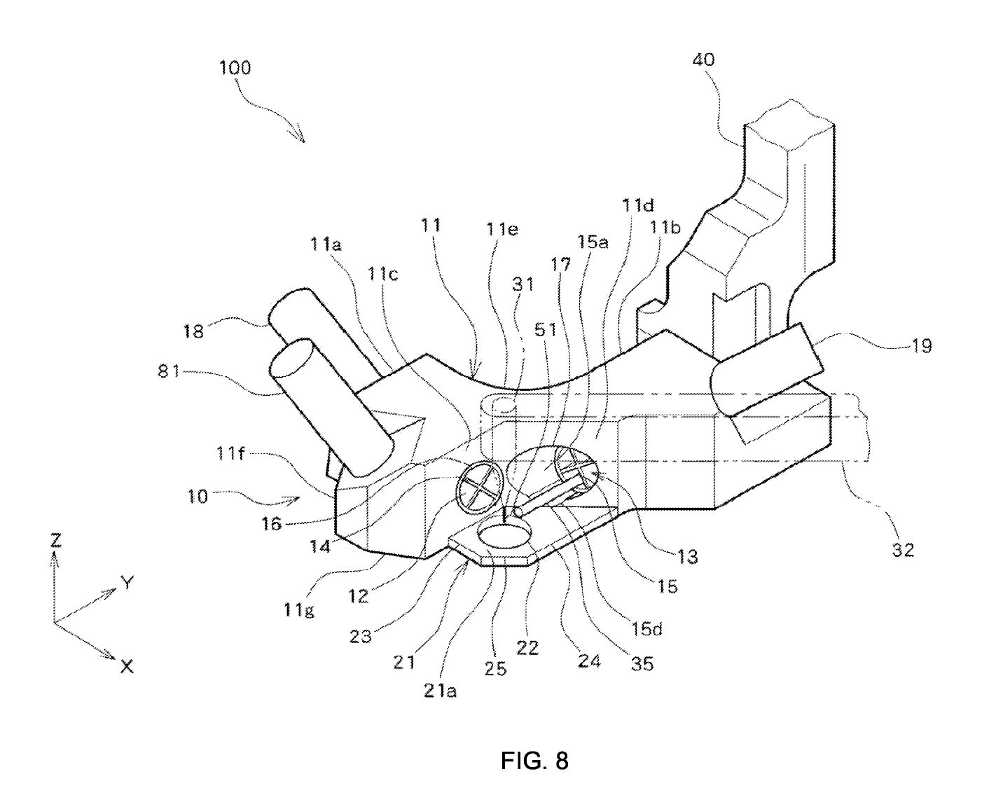

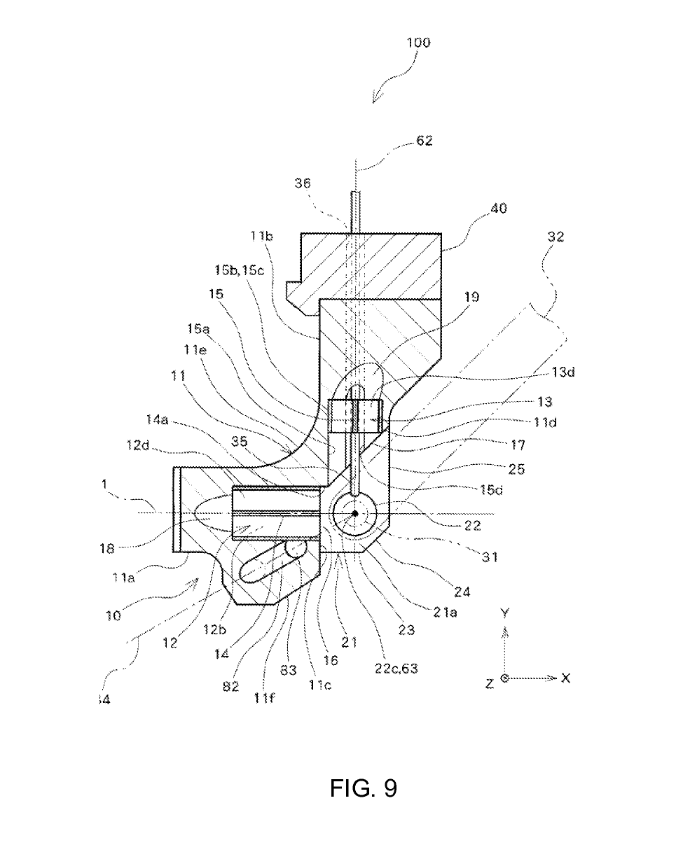

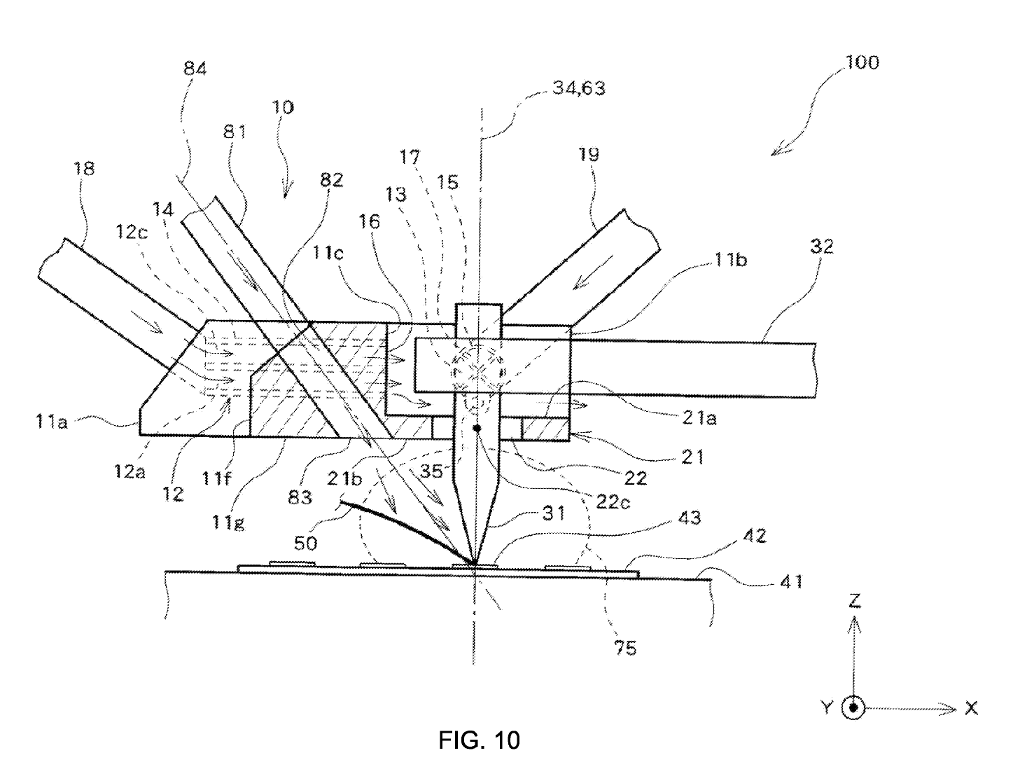

Next, a different exemplary embodiment of the present invention will be described in detail with reference to FIG. 8 to FIG. 12. Like components in the exemplary embodiment described with reference to FIG. 1 through FIG. 7 are shown by like reference numerals and descriptions of such components shall be omitted. As shown in FIG. 8, in the exemplary embodiment, a main body 11 is provided with a first block 11a, a second block 11b, and a third block 11f that projects toward an opposite direction of the second block 11b. A third antioxidant gas supply line 81 is attached to an upper side of the third block 11f, and a third antioxidant gas flow channel 82 penetrates the third block 11f obliquely from an upper surface of the third block 11f to a lower surface 11g as shown in FIG. 9. As shown in FIG. 9, an opening in the lower surface 11g of the third block 11f constitutes a third antioxidant gas outlet 83 for blowing the antioxidant gas obliquely downward from the lower surface 11g. The lower surface 11g of the third block 11f is in the same plane as a lower surface of a horizontal plate 21. As shown in FIG. 9, a centerline 84 of the third antioxidant gas flow channel 82 extends toward a centerline 63 of a through hole 22 as shown in FIG. 10 in a direction substantially the same as a direction in which a bonding arm 32 extends, and directed toward around a tip of a capillary 31 or a contact point between an electrode 43 and the capillary 31. Accordingly, the antioxidant gas from the third antioxidant gas outlet 83 is blown around the electrode 43 with which the capillary 31 is in contact.

Now, an operation of the wire bonding apparatus 100 thus configured will be described with reference to FIG. 10 to FIG. 12. As shown by arrows in a solid line in FIG. 10, the antioxidant gas is supplied from the first, second, and third antioxidant gas supply lines 18, 19 and 81 to the first, second, and third antioxidant gas flow channels 12, 13, 82, respectively, and blown through the outlets 16, 17 and 83. Flows of the antioxidant gas from the first and second antioxidant gas flow channels 12, 13 are directed toward a center 22c of the through hole 22 along the upper surface of the horizontal plate 21, and a flow of the antioxidant gas from the third antioxidant gas outlet 83 is directed toward around the electrode 43 with which the capillary 31 is in contact in the center of the through hole 22. Then, the antioxidant gas from the third antioxidant gas outlet 83 forms a stagnant area beneath the horizontal plate 21, and an antioxidant gas atmosphere area 75 is formed around the tip of the capillary and the electrode 43.

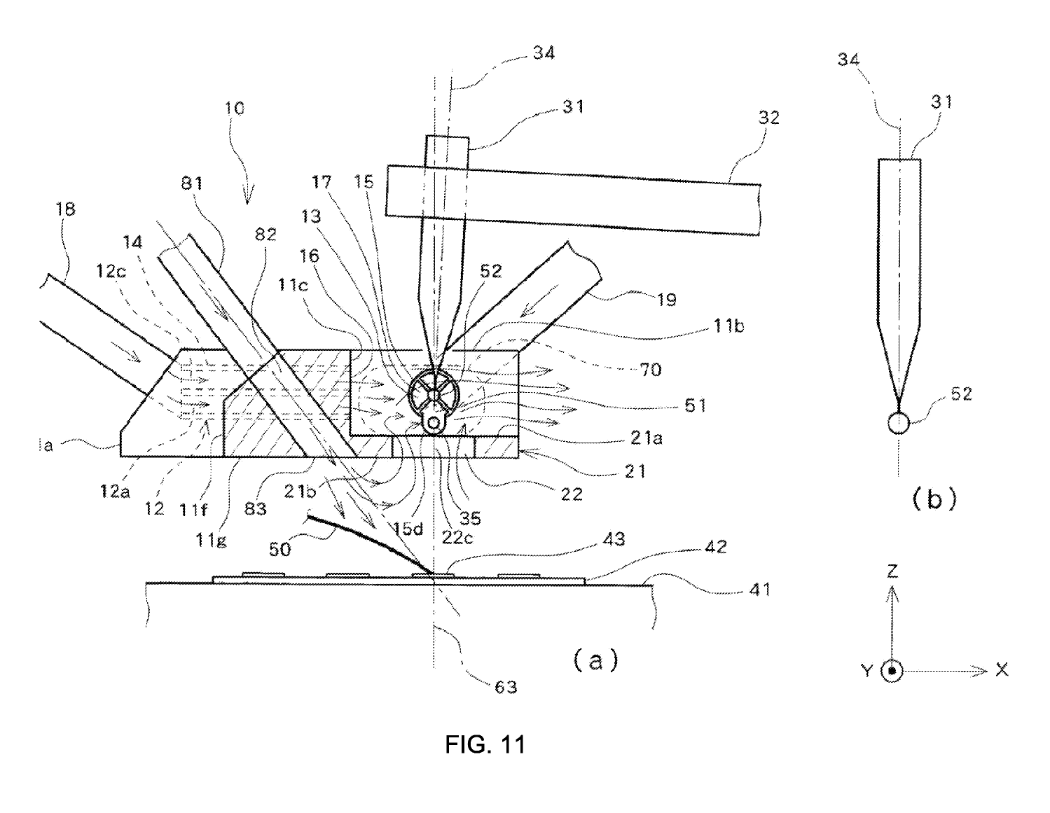

As shown in FIG. 11(a), upon completing a bonding of a wire 50 to the electrode 43, the capillary 31 attached to a tip of the bonding arm 32 is raised by rotation of the bonding arm 32, and the wire tail 51 of a predetermined length extends from the tip of the capillary 31. Then, the capillary is further raised up to a position at which the tip of the capillary 31 comes above an upper surface 21a of the horizontal plate 21 and a lower end of the wire tail 51 comes near a center position of the electrode 35 of EFO.

According to the previous exemplary embodiment that has been described with reference to FIG. 1 to FIG. 7, as shown in FIG. 6(a), when the capillary 31 rises, periphery air of the capillary 31 accompanies the capillary 31 through the through hole 22 above the upper surface 21a of the horizontal plate 21, as shown by arrows in a dotted line in FIG. 6(a). However, according to this exemplary embodiment, as described with reference to FIG. 10, the antioxidant gas atmosphere area 75 is formed under the horizontal plate 21 with the antioxidant gas blown, from the third antioxidant gas outlet 83. Accordingly, when raising the capillary 31 as shown in FIG. 11(a), the antioxidant gas that has stagnated under the horizontal plate 21 comes above the upper surface 21a of the horizontal plate 21 accompanying the capillary 31 through the through hole 22, as shown by arrows in a solid line in FIG. 11(a).

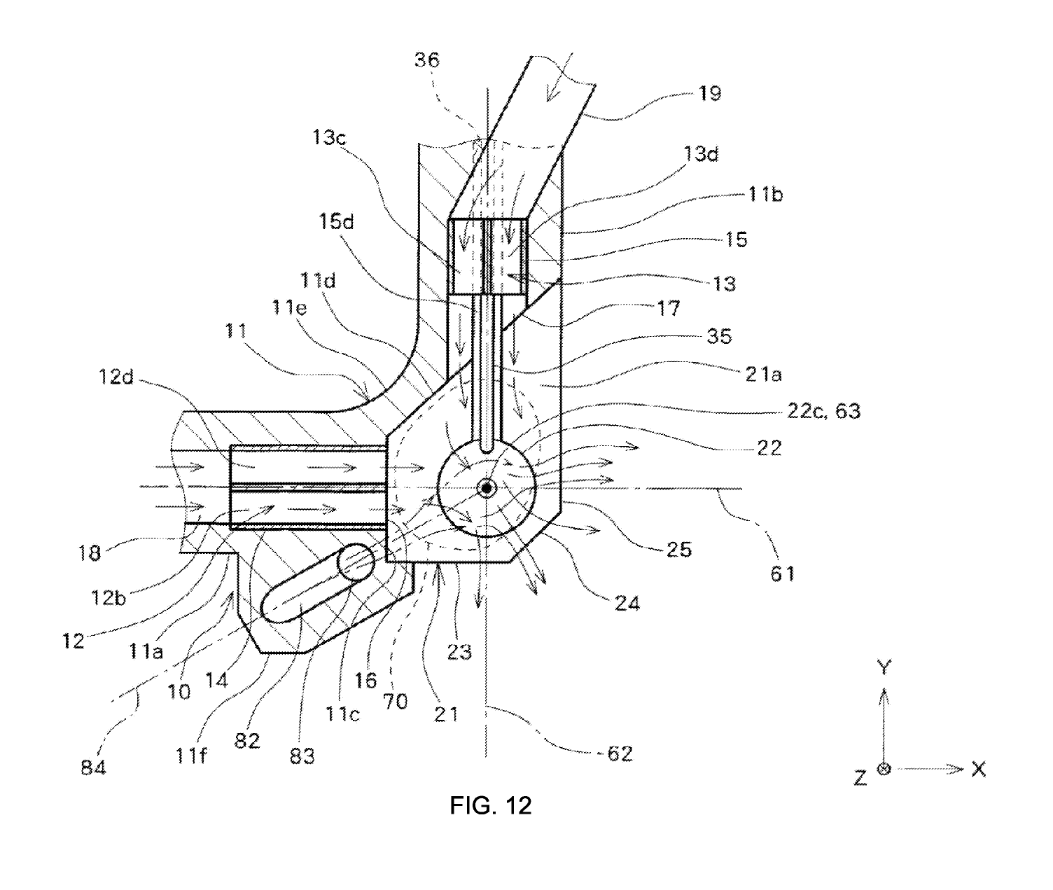

Also, as shown by arrows in a solid line in FIG. 11(a), the antioxidant gas is blown through the outlets 16, 17 of the first and second antioxidant gas flow channels 12, 13 toward the center 22c of the through hole 22 along the upper surface 21a of the horizontal plate 21. As shown in FIG. 12, flows of the antioxidant gas respectively from the outlets 16, 17 move along the centerline 61 (X-direction centerline) and the centerline 62 (Y-direction centerline) over the horizontal plate 21, meet above the through hole 22, and then move outside of the horizontal plate 21 from edges of the horizontal plate 21 that are open without being provided with an antioxidant gas flow channel or a vertical wall surface; the edges including an edge 25 perpendicular to the centerline 61 (X-direction centerline), an edge 23 perpendicular to the centerline 62 (Y-direction centerline), and an edge 24 inclined to the centerline 61 (X-direction centerline) and the centerline 62 (Y-direction centerline). Further, a flow of the antioxidant gas from the third antioxidant gas outlet 83 comes under the lower side of the horizontal plate 21 as shown by arrows in an alternate long and short dash line in FIG. 12, moves above the upper surface 21a of the horizontal plate 21 through the through hole 22, as shown by arrows in an solid line in FIG. 12, and then moves outside of the horizontal plate 21 from the edges 23, 24, and 25 that are opened and without being provided with the vertical walls 11c, 11d. Also, the antioxidant gas blown from the outlets 16, 17 forms a stagnant area by the vertical walls 11c, 11d of the first and second blocks 11a, 11b forming the wall surfaces perpendicular to the horizontal plate 21 to form an antioxidant gas atmosphere area 70 that spreads horizontally including an area of the through hole 22 and an area between the through hole and the vertical walls 11c, 11d, with a height from the upper surface 21a of the horizontal plate 21 to top edges of the vertical walls 11c, 11d, as shown in FIG. 10(a) and, FIG. 12.

In this manner, by forming the antioxidant gas atmosphere area 75 under the horizontal plate 21 beforehand by the antioxidant gas that has been blown from the third antioxidant gas outlet 83, it is possible to form an antioxidant gas atmosphere area 70 on the upper side of the horizontal plate 21 while preventing the air from coming up above the upper surface 21a of the horizontal plate 21 when raising the capillary 31, and thus to effectively prevent oxygen from being mixed into the antioxidant gas atmosphere area 70. Thus, when forming the free air ball 52 at the tip of the capillary 31, as shown in FIG. 11(b) by generating a spark between the electrode 35 of EFO and the wire tail 51 of the tip of the capillary 31 in the antioxidant gas atmosphere area 70, it is possible to effectively prevent oxidation of the surface of the free air ball 52 because the antioxidant gas atmosphere area 70 does not include air containing oxygen.

As described above, in this exemplary embodiment, it is described that the third block 11f is disposed on the side opposite of the second block 11b with respect to the first block 11a of the main body 11, and that the centerline 84 of the third antioxidant gas flow channel 82 extends in the direction substantially the same as the direction in which the bonding arm 32 extends. However, as long as the third antioxidant gas outlet 83 faces the centerline 63 of the through hole 22 and directed toward an area around a position where the capillary 31 is brought into contact with the electrode 43, the facing direction of the third antioxidant gas outlet 83 may align with the centerline 62 in the Y direction, for example.

The present invention is not limited to the above described embodiments, and can include any alteration or modification without departing from the technical scope and the spirit of the present invention as defined in the scope of the present invention.

### DESCRIPTION OF REFERENCE CHARACTERS

10: antioxidant unit
11: main body
11a: first block
11b: second block
11c, 11d: vertical wall surface
11e: curved surface
11f: third block
11g: lower surface
12: first antioxidant gas flow channel
12a to 12d, 13a to 13d: flow channel section
13: second antioxidant gas flow channel
14, 15: guide vane
14a: first hole
14b, 15b: guide vane assembly
14c, 15c: external cylinder
15a: second hole
15d: groove
16, 17: outlet
18: first antioxidant gas supply line
19: second antioxidant gas supply line
21: horizontal plate
21a: upper surface
22: through hole
22c: center
23, 24, 25: edge
31: capillary
32: bonding arm
34, 61, 62, 63: centerline
35: electrode of EFO
36: mounting hole for the electrode of EFO
40: mounting arm
41: bonding stage
42: substrate
43: electrode
50: wire
51: wire tail
52: free air ball
70, 75: antioxidant gas atmosphere area
81: third antioxidant gas supply line
82: third antioxidant gas flow channel
83: third antioxidant gas outlet
100: wire bonding apparatus

What is claimed is:

1. A wire bonding apparatus for bonding an electrode of a semiconductor chip and an electrode of a substrate with a wire, the apparatus comprising:
a bonding tool for bonding a wire to each electrode;
a horizontal plate provided with a through hole allowing a tip of the bonding tool to be inserted and removed;
a first antioxidant gas flow channel for allowing an antioxidant gas to be blown to a center of the through hole along an upper surface of the horizontal plate; and
a second antioxidant gas flow channel for allowing an antioxidant gas to be blown to the center of the through hole along the upper surface of the horizontal plate in a direction substantially intersecting with a direction in which the first antioxidant gas flow channel extends,
wherein the horizontal plate is configured such that the antioxidant gas on the upper surface of the horizontal plate is allowed to flow outside the horizontal plate from edges of the horizontal plate, the edges being provided with no antioxidant gas flow channel.

2. The wire bonding apparatus according to claim 1, further comprising:
a wall surface provided on the upper surface of the horizontal plate,
wherein the wall surface is disposed around a periphery of an outlet of the first antioxidant gas flow channel, around a periphery of an outlet of the second antioxidant gas flow channel, and between the peripheries, the wall surface having the antioxidant gas be stagnated thereabout.

3. The wire bonding apparatus according to claim 2,
wherein the wall surface is provided spaced apart from a periphery of the through hole in the horizontal plate.

4. The wire bonding apparatus according to claim 2,
wherein a portion of each antioxidant gas flow channel connecting to the corresponding outlet is a straight pipe conduit extending along the upper surface of the horizontal plate, and
wherein a guide vane for preventing the antioxidant gas from drifting is provided within an interior portion of each straight pipe conduit.

5. The wire bonding apparatus according to claim 4,
wherein each guide vane comprises flat plates disposed in a crosswise manner, partitioning a cross section of the straight pipe conduit into four sections, and
wherein the flat plates are arranged in a manner inclined with respect to the upper surface of the horizontal plate.

6. The wire bonding apparatus according to claim 1, further comprising:
a third antioxidant gas flow channel for allowing an antioxidant gas to be blown to the center of the through hole obliquely downward from a lower surface of the horizontal plate.

7. The wire bonding apparatus according to claim 6,
wherein the first antioxidant gas flow channel, the second antioxidant gas flow channel, the third antioxidant gas flow channel, and the horizontal plate are provided for a common base unit, and
wherein the common base unit comprises a wall surface arranged around a periphery of an outlet of the first antioxidant gas flow channel, around a periphery of an outlet of the second antioxidant gas flow channel, and between the peripheries, the wall surface having the antioxidant gas be stagnated thereabout.

8. The wire bonding apparatus according to claim 6,
wherein the third antioxidant gas flow channel allows the antioxidant gas to be blown to the tip of the bonding tool.

9. The wire bonding apparatus according to claim 7,
wherein the third antioxidant gas flow channel allows the antioxidant gas to be blown to the tip of the bonding tool.

10. The wire bonding apparatus according to claim 2, further comprising:
an electrode of electronic flame off (EFO) for forming a free air ball by generating a spark between the wire extending at the tip of the bonding tool and thereof, the electrode of EFO extending from either one of the outlets of the first and second antioxidant gas flow channels toward the through hole of the horizontal plate.
